(19) United States
(12) Patent Application Publication
(10) Pub. No.: US 2009/0095957 A1
(43) Pub. Date: Apr. 16, 2009

(54) Display device and method of manufacturing display device

(75) Inventors: Hidekazu Miyake, Mobara (JP); Takuo Kaitoh, Mobara (JP); Takeshi Kuriyagawa, Mobara (JP); Toshio Miyazawa, Chiba (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 12/285,820

(22) Filed: Oct. 15, 2008

(30) Foreign Application Priority Data
Oct. 15, 2007 (JP) 2007-267349

(51) Int. Cl. H01L 33/00; H01L 21/00

(52) U.S. Cl. 257/59; 438/29; 257/E33.001; 257/E21.001

(57) ABSTRACT

To provide a display device, including a polysilicon thin film transistor, which achieves a reduction of an off current with a simple configuration and with only a slight increase in a number of processes. A display device includes: an insulating substrate, and a thin film transistor formed on the insulating substrate, wherein a semiconductor layer of the thin film transistor has a polysilicon layer, a first amorphous silicon layer formed above the polysilicon layer, and a second amorphous silicon layer formed above the first amorphous silicon layer.

The present application claims priority from Japanese applications JP2007-267349 filed on Oct. 15, 2007, the content of which is hereby incorporated by reference into this application.

### BACKGROUND OF THE INVENTION

1. Technical Field

The present invention relates to a display device, and particularly, to a display device including a thin film transistor.

2. Related Art

This kind of display device, having a plurality of pixels arrayed in a matrix form on a display portion thereof, is configured in such a way that individual pixel arrays are sequentially selected by turning on a thin film transistor included in each pixel thereof by means of a scanning signal supplied via a gate signal line and, in accordance with a timing of the selection, an image signal is supplied to individual pixels of a selected pixel array, via a drain signal line commonly connected to corresponding pixels of another pixel array.

Also, it may happen that a drive circuit which drives the display device is formed around a display area formed of collections of the individual pixels, and the drive circuit is also configured including a thin film transistor.

As the thin film transistor, heretofore, one whose semiconductor layer is formed from amorphous silicon has been used. Also, due to a high mobility, one whose semiconductor layer is formed from polysilicon has also been used. Particularly in the drive circuit, a polysilicon thin film transistor has been used.

These thin film transistors are configured of, for example, a gate electrode connected to the gate signal line, a semiconductor layer formed straddling the gate electrode via an insulating film, a drain electrode formed on the semiconductor layer, connected to the drain signal line, and a source electrode connected to a pixel electrode, and formed on the semiconductor layer, facing the drain electrode.

The semiconductor layer between the drain electrode and the source electrode functions as a channel area, and in response to a voltage applied to the gate electrode, a current flows between the drain electrode and the source electrode, via the channel area.

Also, in the thin film transistors, it is a common practice that electric field reduction areas are provided between the channel area and the drain electrode, and between the channel area and the source electrode, respectively. The electric field reduction areas, being configured of a semiconductor layer having a comparatively high resistance, prevents an electric field concentration from occurring between the channel area and the drain electrode, and between the channel area and the source electrode, thereby enabling a reduction of an off current.

Then, a structure, in which these kinds of electric field reduction area are horizontally disposed between a channel area and a drain area, and between the channel area and a source area, of a semiconductor layer, and a structure in which they are vertically disposed overlapping a drain electrode and a source electrode, are known. As the latter structure, a detail is disclosed in JP-A-2001-102584.

In a bottom gate structure polysilicon thin film transistor, an LDD structure is applied in order to reduce an electric field of a drain corner. The application of the LDD structure requiring a photomask and an impurity implantation process, a throughput decreases. Also, as the LDD structure requires space, there is a disadvantage such as an aperture ratio decreasing. Therein, in the heretofore mentioned JP-A-2001-102584, electric field reduction areas are formed in a vertical direction, rather than in a horizontal plane. Specifically, a semiconductor layer performs a function of an electric field reduction. In a case in which the semiconductor layer is thin, an n⁻layer is added in a longitudinal direction, allowing the electric field reduction.

However, in a thin film transistor in which an electric field reduction area is vertically formed, there is a need for a formation of a semiconductor layer functioning as the electric field reduction area, separately from a semiconductor layer functioning as a channel area. For this reason, it has a problem in that its configuration becomes complicated, thereby leading to an increase in a number of manufacturing processes. Also, an off current reduction effect is not sufficient with only the electric field reduction in the vertical direction by means of the semiconductor layer.

### SUMMARY OF THE INVENTION

An object of the invention is to provide a display device including a polysilicon thin film transistor which achieves a reduction of an off current with a very simple configuration, and furthermore, with only a slight increase in a number of processes.

To give a brief description of an outline of typical aspects, among aspects of the invention disclosed in the present application, they are as follows:

1. A display device includes: an insulating substrate, and a thin film transistor formed on the insulating substrate, wherein a semiconductor layer of the thin film transistor has a polysilicon layer, a first amorphous silicon layer formed above the polysilicon layer, and a second amorphous silicon layer formed above the first amorphous silicon layer.

2. A display device includes: an insulating substrate, and a plurality of thin film transistors formed on the insulating substrate, wherein the insulating substrate has a pixel area and a peripheral area surrounding the pixel area, the plurality of thin film transistors have a plurality of first thin film transistors and a plurality of second thin film transistors, the plurality of first thin film transistors are formed in the pixel area, the plurality of second thin film transistors are formed in the peripheral area, a semiconductor layer of the plurality of first thin film transistors has a first amorphous silicon layer and a second amorphous silicon layer formed above the first amorphous silicon layer, and a semiconductor layer of the plurality of second thin film transistors, having a polysilicon layer, has formed thereabove the first amorphous silicon layer and the second amorphous silicon layer.

3. In 1 or 2, the first amorphous silicon layer and the second amorphous silicon layer are different in a hydrogen concentration.

4. In any one of 1 to 3, the hydrogen concentration of the second amorphous silicon layer is smaller than that of the first amorphous silicon layer.

5. In any one of 1 to 4, a thickness of the first amorphous silicon layer is 10 nm or more and 100 nm or less.

6. In any one of 1 to 5, a thickness of the second amorphous silicon layer is 50 nm or more and 100 nm or less.

7. A method of manufacturing a display device including an insulating substrate and a thin film transistor formed on the insulating substrate, the thin film transistor having a semiconductor layer, includes: a first step of forming an amorphous silicon layer, after carrying out a dehydrogenation treatment, applying a laser to the amorphous silicon layer, and causing a crystallization, forming a polysilicon layer; a second step of forming a first amorphous silicon layer above the polysilicon layer; and a third step of forming a second amorphous silicon layer above the first amorphous silicon layer.

To give a brief description of advantages obtained by typical aspects, among the aspects of the invention disclosed in the present application, they are as follows.

It is possible to form a polysilicon thin film transistor which achieves a reduction of an off current with a very simple configuration, and furthermore, with only a slight increase in a number of processes.

Also, it is possible to reduce an off current of a polysilicon thin film transistor, without impairing properties of an amorphous silicon thin film transistor. Also, it is possible to simultaneously form an amorphous silicon thin film transistor and a polysilicon thin film transistor, which have good properties, on the same substrate.

Therefore, it is possible to manufacture at a low cost a display device in which the amorphous silicon thin film transistor is applied to a pixel transistor, and the polysilicon thin film transistor to a drive circuit portion in a periphery.

### BRIEF DESCRIPTION OF THE DRAWINGS

FIG. 1 is a view showing an insulating substrate on which a thin film transistor is formed, in a display device of the invention;

FIG. 2 is a view showing a cross-section structure of a heretofore known polysilicon thin film transistor;

FIG. 3 is a view showing a cross-section structure of a polysilicon thin film transistor of the invention;

FIG. 4 is a view showing a cross-section structure of an amorphous silicon thin film transistor, formed in a display area, of the invention;

FIG. 5 is a diagram showing a comparison of dynamic characteristics of the polysilicon thin film transistors in the heretofore known structure and the invention;

FIG. 6 is a diagram showing a comparison of dynamic characteristics of the amorphous silicon thin film transistors in the heretofore known structure and the invention;

FIGS. 7A and 7B are views showing a process of manufacturing the polysilicon thin film transistor and amorphous thin film transistor of the invention;

FIGS. 8A and 8B are views showing a process of manufacturing the polysilicon thin film transistor and amorphous thin film transistor of the invention, following FIGS. 7A and 7B;

FIGS. 9A and 9B are views showing a process of manufacturing the polysilicon thin film transistor and amorphous thin film transistor of the invention, following FIGS. 8A and 8B;

FIGS. 10A and 10B are views showing a process of manufacturing the polysilicon thin film transistor and amorphous thin film transistor of the invention, following FIGS. 9A and 9B; and

FIGS. 11A and 11B are views showing a process of manufacturing the polysilicon thin film transistor and amorphous thin film transistor of the invention, following FIGS. 10A and 10B.

### DESCRIPTION OF THE PREFERRED EMBODIMENT(S)

Hereafter, a description will be given, with reference to the drawings, of a display device of the invention.

Portions having the same function being indicated by the same reference numerals in all of the drawings for illustrating an embodiment, a repetitive description thereof will be omitted.

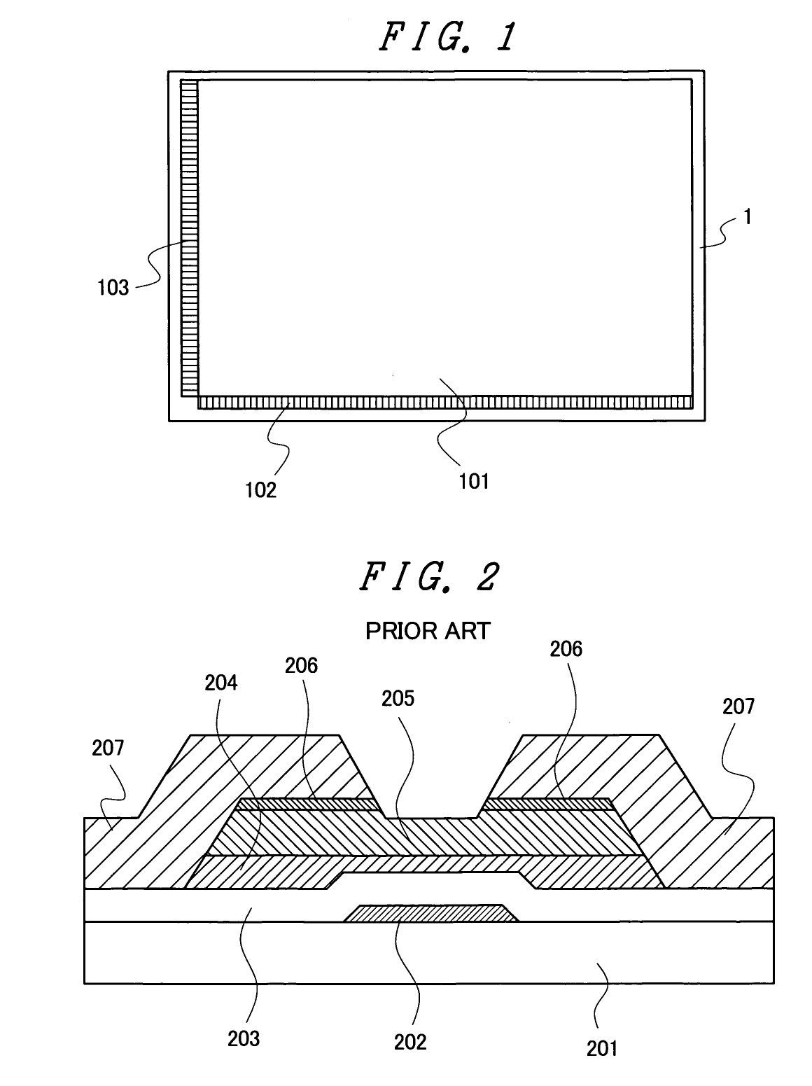

FIG. 1 is a view showing an insulating substrate, configuring the display device of the invention, on which a thin film transistor is formed. An insulating substrate 1 is made of, for example, a glass substrate with glass used as a material.

A display area 101 is formed on the insulating substrate 1. A plurality of pixels are formed in the display area.

Drive circuits, such as an RGB switch 102 and a shift register 103, are formed in a peripheral area outside the display area. The drive circuits are embedded in a top of the insulating substrate 1.

An amorphous silicon thin film transistor is used for the pixels in the display area 101, while a polysilicon thin film transistor is used for the drive circuits in the peripheral area. That is, the amorphous silicon thin film transistor and the polysilicon thin film transistor are simultaneously formed on the same insulating substrate 1.

FIG. 2 is a view showing a cross-section structure of a heretofore known polysilicon thin film transistor, when an amorphous silicon thin film transistor and a polysilicon thin film transistor are simultaneously formed on the same substrate. A gate electrode 202 is formed on a glass substrate 201 which is an insulating substrate, and a gate insulating film 203 is formed thereabove. Furthermore, a polysilicon layer 204 and an amorphous silicon layer 205, forming a channel layer, are formed above the gate insulating film 203. 206 depicts an n⁺amorphous silicon layer, and 207 a source electrode and a drain electrode.

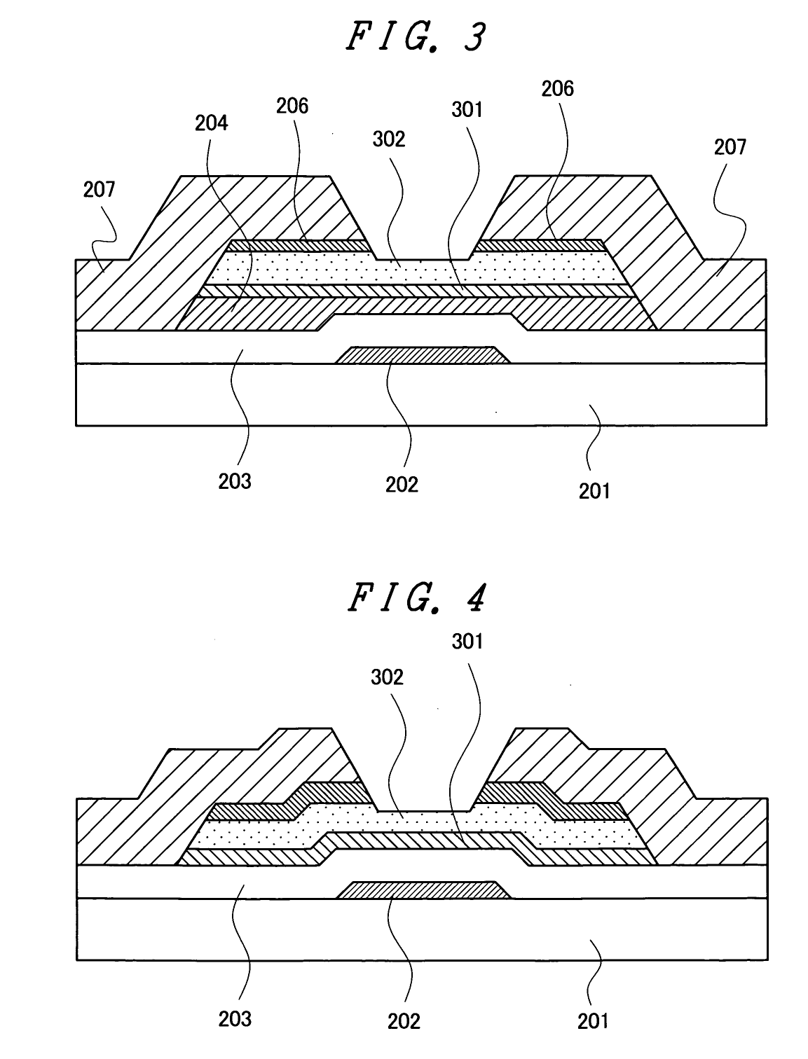

FIG. 3 shows a cross-section structure of the polysilicon thin film transistor of the invention. In comparison with FIG. 2, a difference is that a channel layer is of a three-layer structure formed of the polysilicon layer 204, a first amorphous silicon layer 301 and a second amorphous silicon layer 302. The first amorphous silicon layer 301 and the second amorphous silicon layer 302 are formed from hydrogenated amorphous silicon. A hydrogen concentration of hydrogenated amorphous silicon of the second amorphous silicon layer 302 is smaller than that of the first amorphous silicon layer 301.

FIG. 4 shows a cross-section structure of the amorphous silicon thin film transistor of the invention. In an unshown heretofore known amorphous silicon thin film transistor, there is one amorphous silicon layer as a channel layer. As opposed to this, as shown in FIG. 4, in the amorphous silicon thin film transistor of the invention, a channel layer is of a two-layer structure formed of the first amorphous silicon layer 301 and the second amorphous silicon layer 302. This is because the polysilicon thin film transistor and amorphous silicon thin film transistor, shown in FIG. 3, are simultaneously formed on the same substrate.

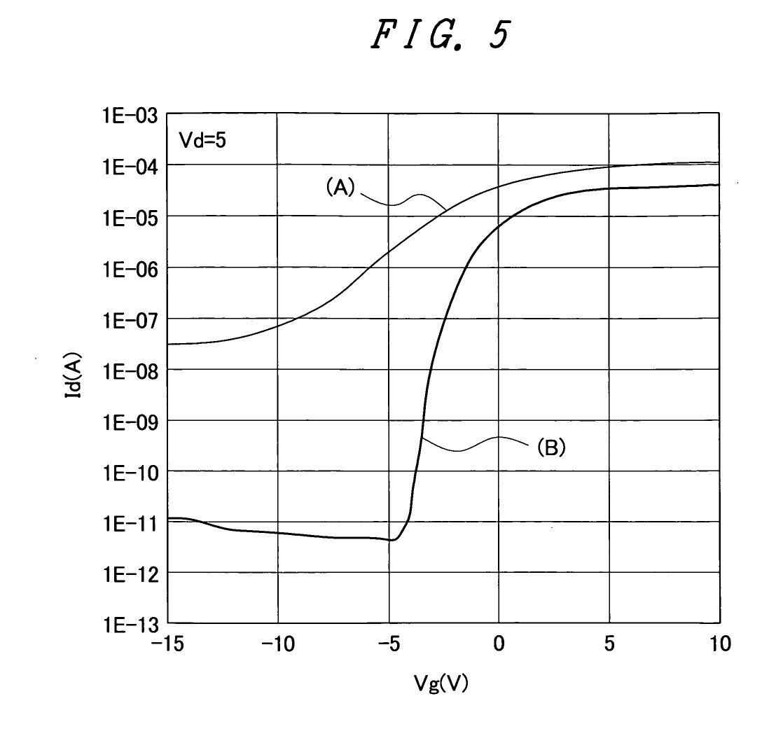

FIG. 5 shows a comparison of dynamic characteristics of the polysilicon thin film transistors in the heretofore known structure and the invention. A horizontal axis shows a gate voltage Vg (V), and a vertical axis shows a drain current Id (A).

In FIG. 5, a curve A shows the characteristic of the heretofore known structure, and a curve B shows the characteristic of the invention. In the heretofore known structure, an off current does not drop completely, and 10 nA or more is flowing, while in the invention, it is reduced to 10 pA or less. This is because a hydrogen concentration of an amorphous silicon layer (the second amorphous silicon layer 302) on a back channel side is reduced, imparting a property of it being difficult for a current to flow.

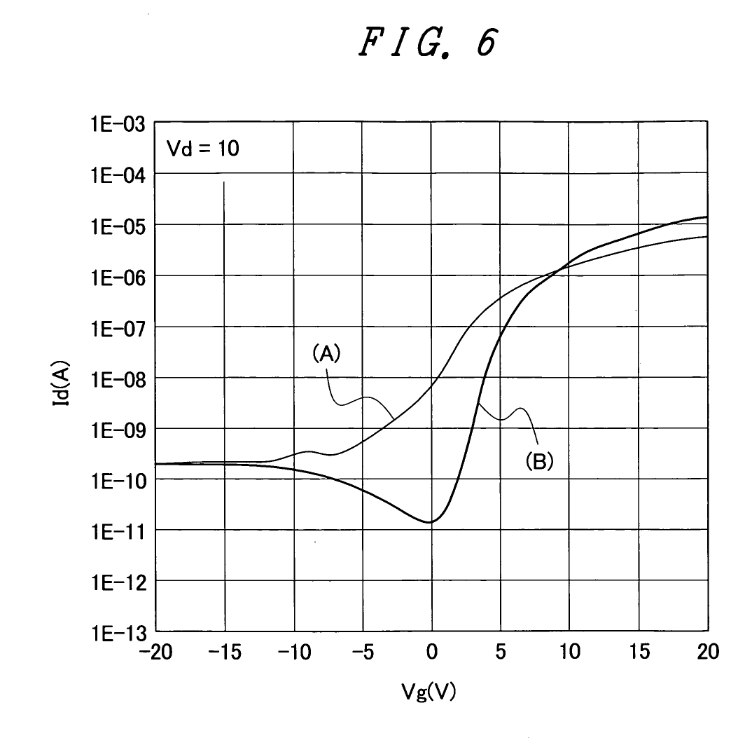

FIG. 6 shows a comparison of dynamic characteristics of the amorphous silicon thin film transistors in the heretofore known structure and the invention. A horizontal axis shows a gate voltage Vg (V), and a vertical axis shows a drain current Id (A).

In FIG. 6, a curve A shows the characteristic of the heretofore known structure, and a curve B shows the characteristic of the invention. As shown in FIG. 6, in the amorphous silicon thin film transistor too, an off current is reduced.

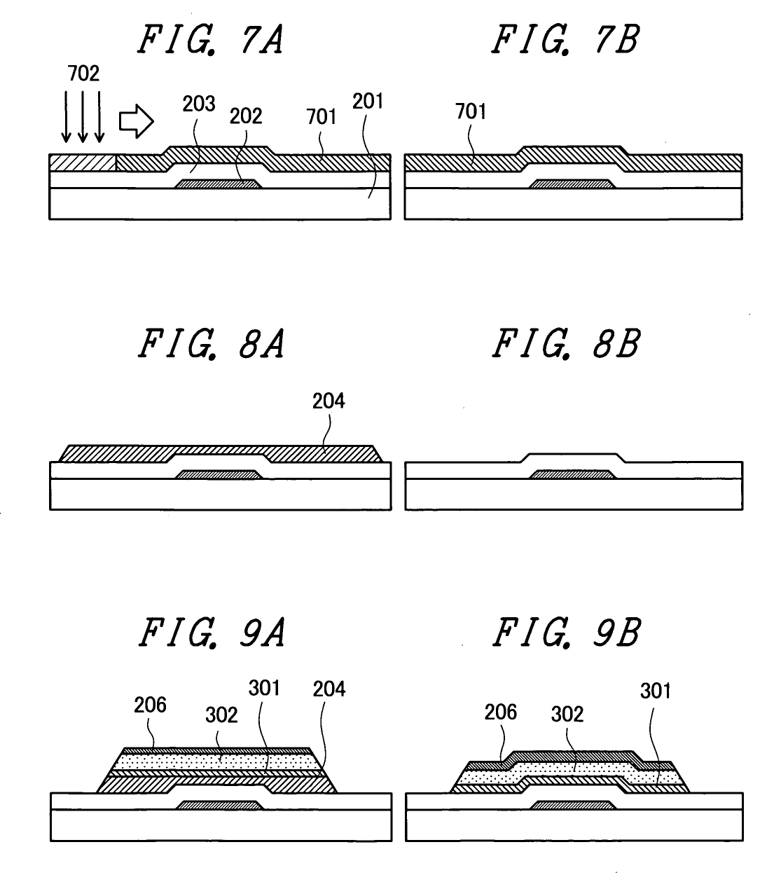

FIGS. 7A and 7B to 11A and 11B show processes of manufacturing the polysilicon thin film transistor and amorphous silicon thin film transistor of the invention.

In FIGS. 7A and 7B to 11A and 11B, A's show a process of manufacturing the polysilicon thin film transistor formed in the peripheral area, and B's show a process of manufacturing the amorphous silicon thin film transistor formed in the display area.

As shown in FIGS. 7A and 7B, a high melting point metal such as molybdenum, or an alloy thereof, is formed into a film with a thickness of around 50 to 150 nm, by a spattering, on the glass substrate 201. Next, the film formed is patterned by a photolithography etching, and processed into the gate electrode 202. Subsequently, an insulating film formed from silicon oxide or silicon nitride is formed to a thickness of around 100 to 300 nm, providing the gate insulating film 203.

Furthermore, an amorphous silicon film 701 is formed to a thickness of around 50 to 300 nm, using a CVD, on the gate insulating film 203, forming a semiconductor film. Furthermore, after carrying out a dehydrogenation treatment, amorphous silicon is crystallized by a pulse or continuous wave laser 702, or the like, forming the polysilicon layer 204. At this time, in the thin film transistor in the display area, shown in FIG. 7B, the crystallization is not carried out, but it is also acceptable to cause the crystallization.

Next, as shown in FIGS. 8A and 8B, only the polysilicon layer 204 in the peripheral area is processed into an island form by a photolithography etching, and the polysilicon layer in the display area is etched away.

Next, as shown in FIGS. 9A and 9B, the first amorphous silicon layer 301, the second amorphous silicon layer 302, and the n⁺amorphous silicon layer 206 are formed to thicknesses of around 10 to 100 nm, 50 to 100 nm, and 10 to 50 nm, respectively, using a CVD, and processed into an island form by a photolithography etching. At this time, the hydrogen concentration of the second amorphous silicon layer 302 is smaller than the hydrogen concentration of the first amorphous silicon layer 301.

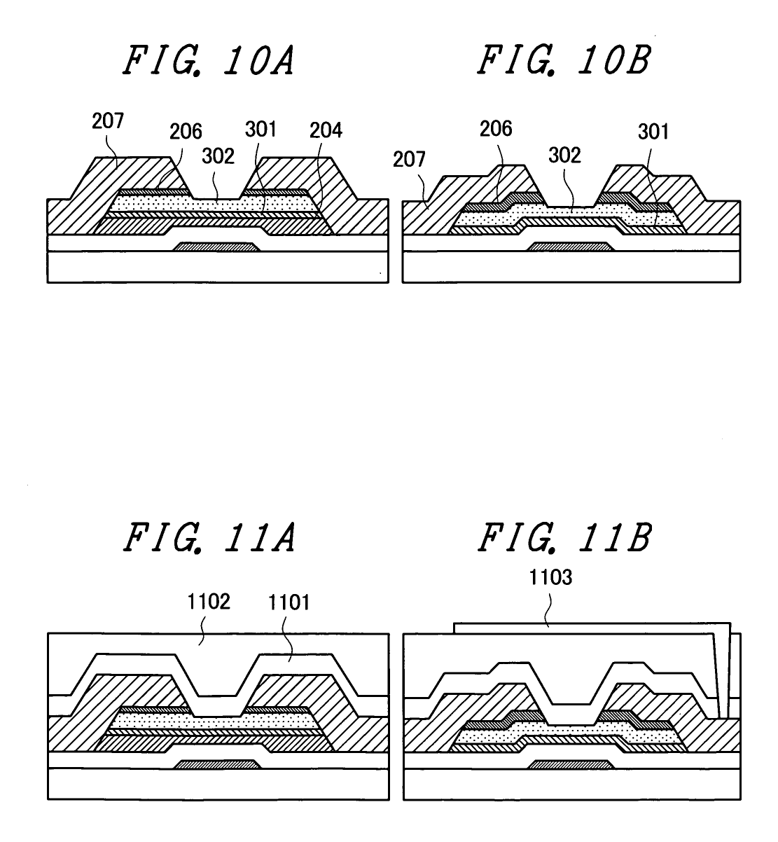

Next, as shown in FIGS. 10A and 10B, in order to form the source electrode and drain electrode, a metal such as aluminum, or an alloy thereof, is formed into a film with a thickness of around 300 to 500 nm by a spattering. At this time, in order to prevent a diffusion of an aluminum film and reduce a contact resistance, it is also acceptable to form a high melting point metal such as titanium or molybdenum, or an alloy thereof, as a barrier metal layer, on a top and a bottom of the aluminum layer. It is sufficient that a thickness of the barrier metal layer is around 30 to 100 nm. Subsequently, the source electrode and drain electrode 207 are formed by a photolithography etching. Also, in order to form a channel of the semiconductor layer, the n⁺amorphous silicon 206 is also etched at this time. Also, one portion of the second amorphous silicon layer 302 is also etched away.

Next, as shown in FIGS. 11A and 11B, as a protective insulating film 1101, for example, silicon nitride is formed into a film with a thickness of around 100 to 200 nm by a CVD. Next, a planarizing organic film 1102 is applied. A contact hole can be formed, using a photosensitive resin as the planarizing organic film 1102, by a photolithography. After forming the contact hole in the protective insulating film 1101 using this as a mask, a transparent conductive film, for example, an ITO, which becomes a pixel electrode 1103, is formed to a thickness of around 30 to 100 nm by a spattering.

According to the heretofore described manufacturing process, it is possible to simultaneously form a polysilicon thin film transistor and an amorphous silicon thin film transistor, which have a good property of an off current being reduced, on the same substrate.

Therefore, it is possible to manufacture at a low cost a display device in which the amorphous silicon thin film transistor is applied to a pixel transistor, and the polysilicon thin film transistor to a drive circuit portion in a periphery.

Heretofore, a specific description has been given, based on the heretofore described embodiment, of the invention contrived by the present inventor, but it goes without saying that the invention, not being limited to the heretofore described embodiment, can be variously modified without departing from its scope.

What is claimed is:

1. A display device comprising: an insulating substrate, and a thin film transistor formed on the insulating substrate, wherein
a semiconductor layer of the thin film transistor has a polysilicon layer, a first amorphous silicon layer formed above the polysilicon layer, and a second amorphous silicon layer formed above the first amorphous silicon layer.

2. A display device comprising: an insulating substrate, and a plurality of thin film transistors formed on the insulating substrate, wherein
the insulating substrate has a pixel area and a peripheral area surrounding the pixel area,
the plurality of thin film transistors have a plurality of first thin film transistors and a plurality of second thin film transistors,
the plurality of first thin film transistors are formed in the pixel area,
the plurality of second thin film transistors are formed in the peripheral area,
a semiconductor layer of the plurality of first thin film transistors has a first amorphous silicon layer and a second amorphous silicon layer formed above the first amorphous silicon layer, and
a semiconductor layer of the plurality of second thin film transistors, having a polysilicon layer, has formed thereabove the first amorphous silicon layer and the second amorphous silicon layer.

3. The display device according to claim 1, wherein
the first amorphous silicon layer and the second amorphous silicon layer are different in a hydrogen concentration.

4. The display device according to claim 2, wherein
the first amorphous silicon layer and the second amorphous silicon layer are different in a hydrogen concentration.

5. The display device according to claim 1, wherein
the hydrogen concentration of the second amorphous silicon layer is smaller than that of the first amorphous silicon layer.

6. The display device according to claim 2, wherein
the hydrogen concentration of the second amorphous silicon layer is smaller than that of the first amorphous silicon layer.

7. The display device according to claim 1, wherein
a thickness of the first amorphous silicon layer is 10 nm or more and 100 nm or less.

8. The display device according to claim 1, wherein
a thickness of the second amorphous silicon layer is 50 nm or more and 100 nm or less.

9. A method of manufacturing a display device including an insulating substrate and a thin film transistor formed on the insulating substrate, the thin film transistor having a semiconductor layer, the method comprising:
a first step of forming an amorphous silicon layer, after carrying out a dehydrogenation treatment, applying a laser to the amorphous silicon layer, and causing a crystallization, forming a polysilicon layer;
a second step of forming a first amorphous silicon layer above the polysilicon layer; and
a third step of forming a second amorphous silicon layer above the first amorphous silicon layer.

10. The method of manufacturing the display device according to claim 9, wherein
the first amorphous silicon layer and the second amorphous silicon layer are different in a hydrogen concentration.

11. The method of manufacturing the display device according to claim 9, wherein
the hydrogen concentration of the second amorphous silicon layer is smaller than that of the first amorphous silicon layer.
